(19) United States
(12) Patent Application Publication
(10) Pub. No.: US 2018/0321872 A1
(43) Pub. Date: Nov. 8, 2018

(54) FRAGMENTED STORAGE MAPS

(71) Applicant: International Business Machines Corporation, Armonk, NY (US)

(72) Inventors: Bart R. Cilfone, Marina del Rey, CA (US); Manish Motwani, Chicago, IL (US); Jason K. Resch, Chicago, IL (US)

(21) Appl. No.: 16/039,742

(22) Filed: Jul. 19, 2018

Related U.S. Application Data
(63) Continuation-in-part of application No. 15/400,529, filed on Jan. 6, 2017, now Pat. No. 10,073,638.
Application No. 15/400,529 is a continuation-in-part of application No. 13/866,457, filed on Apr. 19, 2013, now Pat. No. 9,632,872.
(60) Provisional application No. 61/655,753, filed on Jun. 5, 2012.

(51) Int. Cl. G06F 3/06; G06F 11/10; G11C 29/52

(52) U.S. Cl. CPC G06F 3/0647; G06F 11/1076; G06F 3/067; G06F 3/0619; G11C 29/52

(57) ABSTRACT

A computing device includes an interface configured to interface and communicate with a dispersed storage network (DSN), a memory that stores operational instructions, and processing circuitry operably coupled to the interface and to the memory. The processing circuitry is configured to execute the operational instructions to perform various operations and functions. The computing device obtains DSN address range assignments for at least two other storage units (SUs) based on addition of a SU. The computing device also determines a common address range magnitude to transfer. Then, for each of the at least two other SUs, the computing device selects a corresponding SU address range and also facilitates transferring corresponding encoded data slices (EDSs) that are associated with at least one data object and corresponding DSN address range assignments for each of the corresponding SU address ranges from the at least two other SUs to the first SU.

### CROSS REFERENCE TO RELATED PATENTS

The present U.S. Utility patent application also claims priority pursuant to 35 U.S.C. § 120, as a continuation-in-part (CIP) of U.S. Utility patent application Ser. No. 15/400,529, entitled “AUTOMATIC NAMESPACE ORDERING DETERMINATION,” filed Jan. 6, 2017, pending, which claims priority pursuant to 35 U.S.C. § 120, as a continuation-in-part (CIP) of U.S. Utility patent application Ser. No. 13/866,457, entitled “REPRIORITIZING PENDING DISPERSED STORAGE NETWORK REQUESTS,” filed Apr. 19, 2013, now issued as U.S. Pat. No. 9,632,872 on Apr. 25, 2017, which claims priority pursuant to 35 U.S.C. § 119(e) to U.S. Provisional Application No. 61/655,753, entitled “ESTABLISHING AN ADDRESS RANGE ASSIGNMENT IN A DISTRIBUTED STORAGE AND TASK NETWORK,” filed Jun. 5, 2012, expired. All of the above-referenced patent applications and patents are hereby incorporated herein by reference in their entirety and made part of the present U.S. Utility patent application for all purposes.

### STATEMENT REGARDING FEDERALLY SPONSORED RESEARCH OR DEVELOPMENT

Not applicable.

### INCORPORATION-BY-REFERENCE OF MATERIAL SUBMITTED ON A COMPACT DISC

Not applicable.

### BACKGROUND OF THE INVENTION

### Technical Field of the Invention

This invention relates generally to computer networks and more particularly to dispersing error encoded data.

### Description of Related Art

Computing devices are known to communicate data, process data, and/or store data. Such computing devices range from wireless smart phones, laptops, tablets, personal computers (PC), work stations, and video game devices, to data centers that support millions of web searches, stock trades, or on-line purchases every day. In general, a computing device includes a central processing unit (CPU), a memory system, user input/output interfaces, peripheral device interfaces, and an interconnecting bus structure.

As is further known, a computer may effectively extend its CPU by using “cloud computing” to perform one or more computing functions (e.g., a service, an application, an algorithm, an arithmetic logic function, etc.) on behalf of the computer. Further, for large services, applications, and/or functions, cloud computing may be performed by multiple cloud computing resources in a distributed manner to improve the response time for completion of the service, application, and/or function. For example, Hadoop is an open source software framework that supports distributed applications enabling application execution by thousands of computers.

In addition to cloud computing, a computer may use “cloud storage” as part of its memory system. As is known, cloud storage enables a user, via its computer, to store files, applications, etc. on an Internet storage system. The Internet storage system may include a RAID (redundant array of independent disks) system and/or a dispersed storage system that uses an error correction scheme to encode data for storage.

Within prior art data storage systems, certain additional components maybe added from time. when this happens, the prior art does not provide adequate means by which the overall system may accommodate such new components without adversely affecting the performance of the overall system. There continues to be a need for improvement in the manner by which prior art data storage systems operate to provide for acceptable performance while meeting the ever-increasing demands and requirements of data storage systems.

### BRIEF DESCRIPTION OF THE SEVERAL VIEWS OF THE DRAWING(S)

FIG. 1 is a schematic block diagram of an embodiment of a dispersed or distributed storage network (DSN) in accordance with the present invention;

FIG. 2 is a schematic block diagram of an embodiment of a computing core in accordance with the present invention;

FIG. 3 is a schematic block diagram of an example of dispersed storage error encoding of data in accordance with the present invention;

FIG. 4 is a schematic block diagram of a generic example of an error encoding function in accordance with the present invention;

FIG. 5 is a schematic block diagram of a specific example of an error encoding function in accordance with the present invention;

FIG. 6 is a schematic block diagram of an example of a slice name of an encoded data slice (EDS) in accordance with the present invention;

FIG. 7 is a schematic block diagram of an example of dispersed storage error decoding of data in accordance with the present invention;

FIG. 8 is a schematic block diagram of a generic example of an error decoding function in accordance with the present invention;

FIG. 9A is a diagram illustrating an example of an address range mapping in accordance with the present invention;

FIG. 9B is a diagram illustrating another example of an address range mapping in accordance with the present invention;

FIG. 9C is a diagram illustrating another example of an address range mapping in accordance with the present invention; and

FIG. 10 is a flowchart illustrating an example of updating an address range assignment in accordance with the present invention.

### DETAILED DESCRIPTION OF THE INVENTION

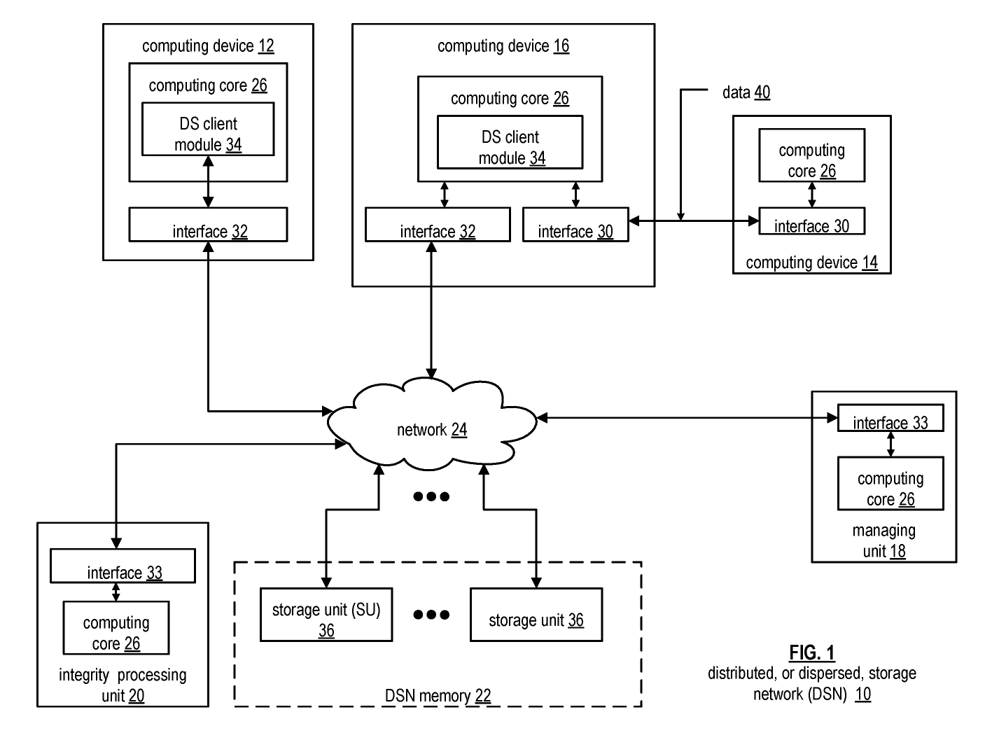

FIG. 1 is a schematic block diagram of an embodiment of a dispersed, or distributed, storage network (DSN) 10 that includes a plurality of computing devices 12-16, a managing unit 18, an integrity processing unit 20, and a DSN memory 22. The components of the DSN 10 are coupled to a network 24, which may include one or more wireless and/or wire lined communication systems; one or more non-public intranet systems and/or public internet systems; and/or one or more local area networks (LAN) and/or wide area networks (WAN).

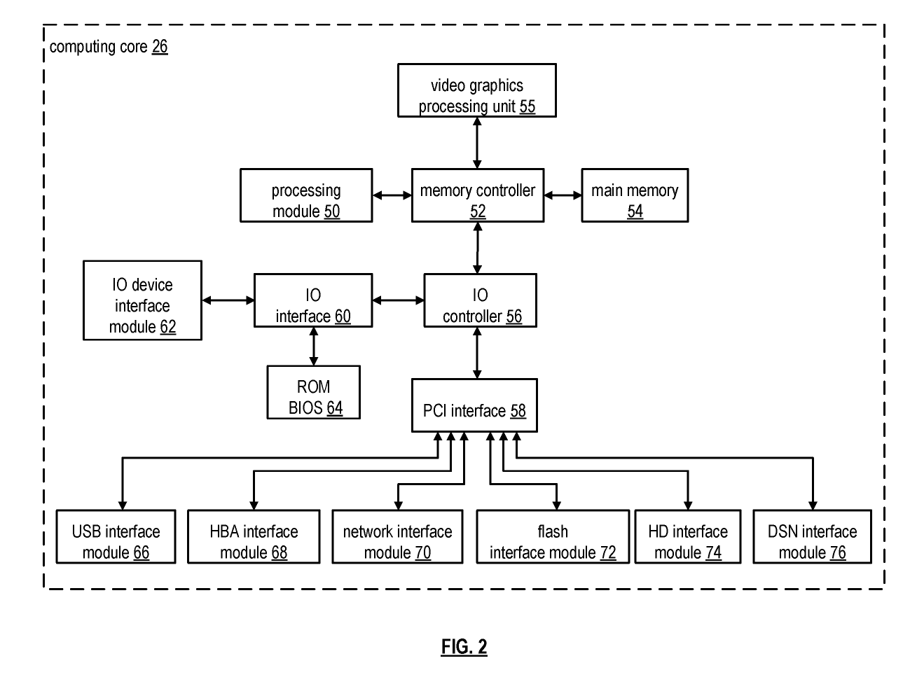

The DSN memory 22 includes a plurality of storage units 36 that may be located at geographically different sites (e.g., one in Chicago, one in Milwaukee, etc.), at a common site, or a combination thereof. For example, if the DSN memory 22 includes eight storage units 36, each storage unit is located at a different site. As another example, if the DSN memory 22 includes eight storage units 36, all eight storage units are located at the same site. As yet another example, if the DSN memory 22 includes eight storage units 36, a first pair of storage units are at a first common site, a second pair of storage units are at a second common site, a third pair of storage units are at a third common site, and a fourth pair of storage units are at a fourth common site. Note that a DSN memory 22 may include more or less than eight storage units 36. Further note that each storage unit 36 includes a computing core (as shown in FIG. 2, or components thereof) and a plurality of memory devices for storing dispersed error encoded data.

Each of the computing devices 12-16, the managing unit 18, and the integrity processing unit 20 include a computing core 26, which includes network interfaces 30-33. Computing devices 12-16 may each be a portable computing device and/or a fixed computing device. A portable computing device may be a social networking device, a gaming device, a cell phone, a smart phone, a digital assistant, a digital music player, a digital video player, a laptop computer, a handheld computer, a tablet, a video game controller, and/or any other portable device that includes a computing core. A fixed computing device may be a computer (PC), a computer server, a cable set-top box, a satellite receiver, a television set, a printer, a fax machine, home entertainment equipment, a video game console, and/or any type of home or office computing equipment. Note that each of the managing unit 18 and the integrity processing unit 20 may be separate computing devices, may be a common computing device, and/or may be integrated into one or more of the computing devices 12-16 and/or into one or more of the storage units 36.

Each interface 30, 32, and 33 includes software and hardware to support one or more communication links via the network 24 indirectly and/or directly. For example, interface 30 supports a communication link (e.g., wired, wireless, direct, via a LAN, via the network 24, etc.) between computing devices 14 and 16. As another example, interface 32 supports communication links (e.g., a wired connection, a wireless connection, a LAN connection, and/or any other type of connection to/from the network 24) between computing devices 12 & 16 and the DSN memory 22. As yet another example, interface 33 supports a communication link for each of the managing unit 18 and the integrity processing unit 20 to the network 24.

Computing devices 12 and 16 include a dispersed storage (DS) client module 34, which enables the computing device to dispersed storage error encode and decode data as subsequently described with reference to one or more of FIGS. 3-8. In this example embodiment, computing device 16 functions as a dispersed storage processing agent for computing device 14. In this role, computing device 16 dispersed storage error encodes and decodes data on behalf of computing device 14. With the use of dispersed storage error encoding and decoding, the DSN 10 is tolerant of a significant number of storage unit failures (the number of failures is based on parameters of the dispersed storage error encoding function) without loss of data and without the need for a redundant or backup copies of the data. Further, the DSN 10 stores data for an indefinite period of time without data loss and in a secure manner (e.g., the system is very resistant to unauthorized attempts at accessing the data).

In operation, the managing unit 18 performs DS management services. For example, the managing unit 18 establishes distributed data storage parameters (e.g., vault creation, distributed storage parameters, security parameters, billing information, user profile information, etc.) for computing devices 12-14 individually or as part of a group of user devices. As a specific example, the managing unit 18 coordinates creation of a vault (e.g., a virtual memory block associated with a portion of an overall namespace of the DSN) within the DSN memory 22 for a user device, a group of devices, or for public access and establishes per vault dispersed storage (DS) error encoding parameters for a vault. The managing unit 18 facilitates storage of DS error encoding parameters for each vault by updating registry information of the DSN 10, where the registry information may be stored in the DSN memory 22, a computing device 12-16, the managing unit 18, and/or the integrity processing unit 20.

The DSN managing unit 18 creates and stores user profile information (e.g., an access control list (ACL)) in local memory and/or within memory of the DSN module 22. The user profile information includes authentication information, permissions, and/or the security parameters. The security parameters may include encryption/decryption scheme, one or more encryption keys, key generation scheme, and/or data encoding/decoding scheme.

The DSN managing unit 18 creates billing information for a particular user, a user group, a vault access, public vault access, etc. For instance, the DSN managing unit 18 tracks the number of times a user accesses a non-public vault and/or public vaults, which can be used to generate a per-access billing information. In another instance, the DSN managing unit 18 tracks the amount of data stored and/or retrieved by a user device and/or a user group, which can be used to generate a per-data-amount billing information.

As another example, the managing unit 18 performs network operations, network administration, and/or network maintenance. Network operations includes authenticating user data allocation requests (e.g., read and/or write requests), managing creation of vaults, establishing authentication credentials for user devices, adding/deleting components (e.g., user devices, storage units, and/or computing devices with a DS client module 34) to/from the DSN 10, and/or establishing authentication credentials for the storage units 36. Network administration includes monitoring devices and/or units for failures, maintaining vault information, determining device and/or unit activation status, determining device and/or unit loading, and/or determining any other system level operation that affects the performance level of the DSN 10. Network maintenance includes facilitating replacing, upgrading, repairing, and/or expanding a device and/or unit of the DSN 10.

The integrity processing unit 20 performs rebuilding of ‘bad’ or missing encoded data slices. At a high level, the integrity processing unit 20 performs rebuilding by periodically attempting to retrieve/list encoded data slices, and/or slice names of the encoded data slices, from the DSN memory 22. For retrieved encoded slices, they are checked for errors due to data corruption, outdated version, etc. If a slice includes an error, it is flagged as a ‘bad’ slice. For encoded data slices that were not received and/or not listed, they are flagged as missing slices. Bad and/or missing slices are subsequently rebuilt using other retrieved encoded data slices that are deemed to be good slices to produce rebuilt slices. The rebuilt slices are stored in the DSN memory 22.

FIG. 2 is a schematic block diagram of an embodiment of a computing core 26 that includes a processing module 50, a memory controller 52, main memory 54, a video graphics processing unit 55, an input/output (IO) controller 56, a peripheral component interconnect (PCI) interface 58, an IO interface module 60, at least one IO device interface module 62, a read only memory (ROM) basic input output system (BIOS) 64, and one or more memory interface modules. The one or more memory interface module(s) includes one or more of a universal serial bus (USB) interface module 66, a host bus adapter (HBA) interface module 68, a network interface module 70, a flash interface module 72, a hard drive interface module 74, and a DSN interface module 76.

The DSN interface module 76 functions to mimic a conventional operating system (OS) file system interface (e.g., network file system (NFS), flash file system (FFS), disk file system (DFS), file transfer protocol (FTP), web-based distributed authoring and versioning (WebDAV), etc.) and/or a block memory interface (e.g., small computer system interface (SCSI), internet small computer system interface (iSCSI), etc.). The DSN interface module 76 and/or the network interface module 70 may function as one or more of the interface 30-33 of FIG. 1. Note that the IO device interface module 62 and/or the memory interface modules 66-76 may be collectively or individually referred to as IO ports.

FIG. 3 is a schematic block diagram of an example of dispersed storage error encoding of data. When a computing device 12 or 16 has data to store it disperse storage error encodes the data in accordance with a dispersed storage error encoding process based on dispersed storage error encoding parameters. The dispersed storage error encoding parameters include an encoding function (e.g., information dispersal algorithm, Reed-Solomon, Cauchy Reed-Solomon, systematic encoding, non-systematic encoding, on-line codes, etc.), a data segmenting protocol (e.g., data segment size, fixed, variable, etc.), and per data segment encoding values. The per data segment encoding values include a total, or pillar width, number (T) of encoded data slices per encoding of a data segment i.e., in a set of encoded data slices); a decode threshold number (D) of encoded data slices of a set of encoded data slices that are needed to recover the data segment; a read threshold number (R) of encoded data slices to indicate a number of encoded data slices per set to be read from storage for decoding of the data segment; and/or a write threshold number (W) to indicate a number of encoded data slices per set that must be accurately stored before the encoded data segment is deemed to have been properly stored. The dispersed storage error encoding parameters may further include slicing information (e.g., the number of encoded data slices that will be created for each data segment) and/or slice security information (e.g., per encoded data slice encryption, compression, integrity checksum, etc.).

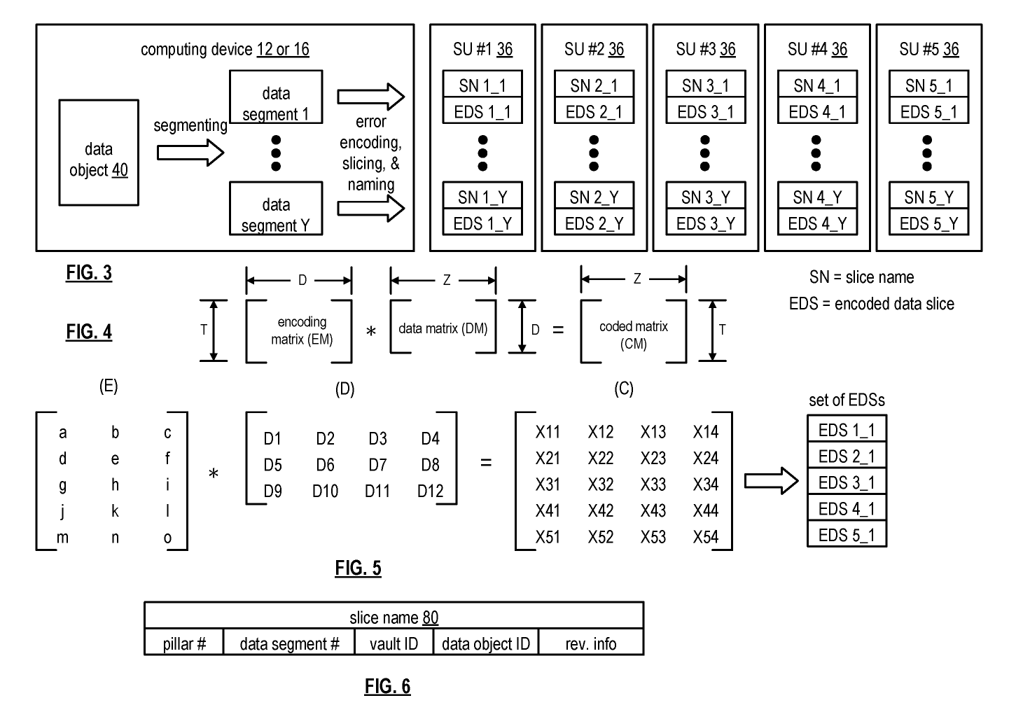

In the present example, Cauchy Reed-Solomon has been selected as the encoding function (a generic example is shown in FIG. 4 and a specific example is shown in FIG. 5); the data segmenting protocol is to divide the data object into fixed sized data segments; and the per data segment encoding values include: a pillar width of 5, a decode threshold of 3, a read threshold of 4, and a write threshold of 4. In accordance with the data segmenting protocol, the computing device 12 or 16 divides the data (e.g., a file (e.g., text, video, audio, etc.), a data object, or other data arrangement) into a plurality of fixed sized data segments (e.g., 1 through Y of a fixed size in range of Kilo-bytes to Tera-bytes or more). The number of data segments created is dependent of the size of the data and the data segmenting protocol.

The computing device 12 or 16 then disperse storage error encodes a data segment using the selected encoding function (e.g., Cauchy Reed-Solomon) to produce a set of encoded data slices. FIG. 4 illustrates a generic Cauchy Reed-Solomon encoding function, which includes an encoding matrix (EM), a data matrix (DM), and a coded matrix (CM). The size of the encoding matrix (EM) is dependent on the pillar width number (T) and the decode threshold number (D) of selected per data segment encoding values. To produce the data matrix (DM), the data segment is divided into a plurality of data blocks and the data blocks are arranged into D number of rows with Z data blocks per row. Note that Z is a function of the number of data blocks created from the data segment and the decode threshold number (D). The coded matrix is produced by matrix multiplying the data matrix by the encoding matrix.

FIG. 5 illustrates a specific example of Cauchy Reed-Solomon encoding with a pillar number (T) of five and decode threshold number of three. In this example, a first data segment is divided into twelve data blocks (D1-D12). The coded matrix includes five rows of coded data blocks, where the first row of X11-X14 corresponds to a first encoded data slice (EDS 1_1), the second row of X21-X24 corresponds to a second encoded data slice (EDS 2_1), the third row of X31-X34 corresponds to a third encoded data slice (EDS 3_1), the fourth row of X41-X44 corresponds to a fourth encoded data slice (EDS 4_1), and the fifth row of X51-X54 corresponds to a fifth encoded data slice (EDS 5_1). Note that the second number of the EDS designation corresponds to the data segment number.

Returning to the discussion of FIG. 3, the computing device also creates a slice name (SN) for each encoded data slice (EDS) in the set of encoded data slices. A typical format for a slice name 60 is shown in FIG. 6. As shown, the slice name (SN) 60 includes a pillar number of the encoded data slice (e.g., one of 1−T), a data segment number (e.g., one of 1−Y), a vault identifier (ID), a data object identifier (ID), and may further include revision level information of the encoded data slices. The slice name functions as, at least part of, a DSN address for the encoded data slice for storage and retrieval from the DSN memory 22.

As a result of encoding, the computing device 12 or 16 produces a plurality of sets of encoded data slices, which are provided with their respective slice names to the storage units for storage. As shown, the first set of encoded data slices includes EDS 1_1 through EDS 5_1 and the first set of slice names includes SN 1_1 through SN 5_1 and the last set of encoded data slices includes EDS 1_Y through EDS 5_Y and the last set of slice names includes SN 1_Y through SN 5_Y.

FIG. 7 is a schematic block diagram of an example of dispersed storage error decoding of a data object that was dispersed storage error encoded and stored in the example of FIG. 4. In this example, the computing device 12 or 16 retrieves from the storage units at least the decode threshold number of encoded data slices per data segment. As a specific example, the computing device retrieves a read threshold number of encoded data slices.

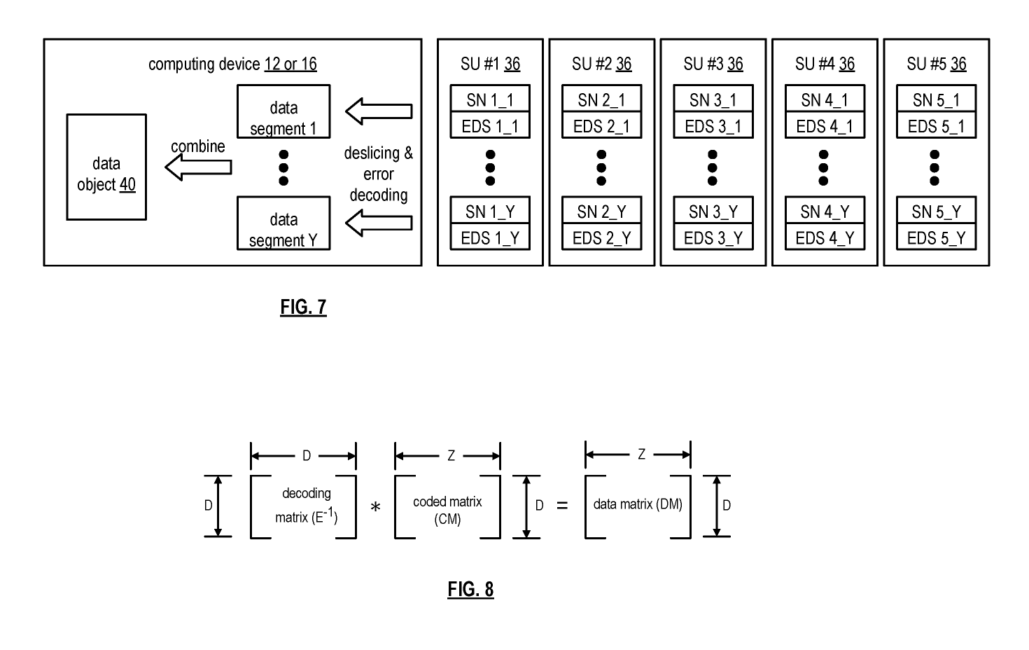

To recover a data segment from a decode threshold number of encoded data slices, the computing device uses a decoding function as shown in FIG. 8. As shown, the decoding function is essentially an inverse of the encoding function of FIG. 4. The coded matrix includes a decode threshold number of rows (e.g., three in this example) and the decoding matrix in an inversion of the encoding matrix that includes the corresponding rows of the coded matrix. For example, if the coded matrix includes rows 1, 2, and 4, the encoding matrix is reduced to rows 1, 2, and 4, and then inverted to produce the decoding matrix.

In some examples, note that dispersed or distributed storage network (DSN) memory includes one or more of a plurality of storage units (SUs) such as SUs 36 (e.g., that may alternatively be referred to a distributed storage and/or task network (DSTN) module that includes a plurality of distributed storage and/or task (DST) execution units 36 that may be located at geographically different sites (e.g., one in Chicago, one in Milwaukee, etc.). Each of the SUs (e.g., alternatively referred to as DST execution units in some examples) is operable to store dispersed error encoded data and/or to execute, in a distributed manner, one or more tasks on data. The tasks may be a simple function (e.g., a mathematical function, a logic function, an identify function, a find function, a search engine function, a replace function, etc.), a complex function (e.g., compression, human and/or computer language translation, text-to-voice conversion, voice-to-text conversion, etc.), multiple simple and/or complex functions, one or more algorithms, one or more applications, etc.

In addition, a computing device (e.g., alternatively referred to as DST processing unit in some examples) is operable to perform various functions, operations, etc. including to generate dispersed error encoded data. In some examples, a computing device is configured to process a data object to generate a plurality of data segments (such that the data object is segmented into a plurality of data segments). Then, the computing device is configured to dispersed error encode the plurality of data segments in accordance with dispersed error encoding parameters to produce sets of encoded data slices (EDSs). In some examples, the computing device is configured to dispersed error encode a data segment of the plurality of data segments in accordance with the dispersed error encoding parameters to produce a set of EDSs. In certain examples, the set of EDSs is distributedly stored in a set of storage units (SUs) within the DSN. That same computing device (and/or another computing device) is configured to retrieve an appropriate number of the set of EDSs (e.g., decode threshold, read threshold, etc.) to reconstruct the data segment in accordance with the dispersed error encoding parameters and/or dispersed error decoding parameters.

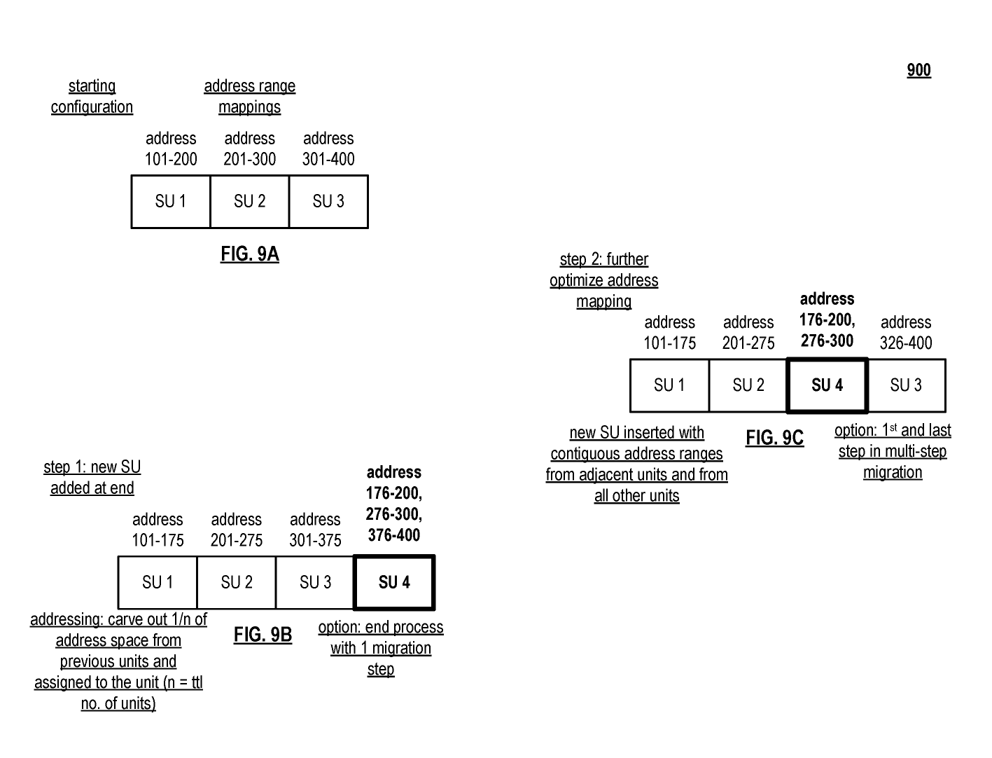

FIG. 9A is a diagram illustrating an example 901 of an address range mapping in accordance with the present invention. This includes a diagram illustrating an example of an address range mapping for a set of storage units (SUs) of a common site. For example, a common site includes SUs 1-3. The address range of the address range mapping includes a dispersed or distributed storage network (DSN) address range including at least one of a source name range and/or a slice name range. The address range mapping may include a site address range mapping (e.g., for a pillar of particular vault) and for each SU of the set of SUs, a SU address range mapping. For example, a site address range mapping includes a slice name address range of 101-400 for a first vault and each of three SUs are mapped to an equal amount of address range space of the site address range. For instance, SU 1 is mapped to slice name address range 101-200, SU 2 is mapped to slice name address range 201-300, and SU 3 is mapped to slice name address range 301-400.

Address range mapping of a SU enables subsequent slice access for one or more slices associated with one or more addresses of the address range of the SU. At a first point in time, SU 2 may store 1 gigabytes (GB) of slices within its address range utilizing one fourth of a 4 GB capacity. At a subsequent point in time, SU 2 may store 3 GB of slices within its address range utilizing three fourths of the 4 GB capacity. As time goes on, an unfavorable capacity utilization level may be reached such that an additional SU may be required to facilitate storing more data within the same site address range. This diagram represents a starting configuration of an example of redistributing the address range mapping when an additional SU is added to the common site and is affiliated with one or more other SUs at the common site (e.g., of a common vault). FIGS. 48B-C represent successive steps in the example of redistributing the address range mapping.

FIG. 9B is a diagram illustrating another example 902 of an address range mapping in accordance with the present invention. This includes a diagram illustrating another example of an address range mapping for a set of legacy distributed storage and task (DST) execution units 1-3 of a common site where additional SU 4 is added in a first address range migration step to the common site providing additional storage capacity within a site address range. In the first address range migration step, a common address range magnitude to transfer from each of the legacy SUs is determined as a per-unit address range divided by a total number of units (e.g., including the legacy SUs and the additional SU). For example, the common address range magnitude to transfer is determined as 100 addresses/4 units=25 addresses per unit.

The first address range migration step further includes transferring the common address range magnitude to transfer of addresses from each of the legacy SUs to the additional SU. The transferring of addresses includes selecting addresses of the addresses to transferred. The selecting may be based on one or more of a predetermination, a selection scheme, selecting a high end, selecting the low end, selecting the middle portion, selecting a contiguous portion, and selecting random addresses. For example, contiguous addresses at a high-end of each of the SU address ranges are selected when the selection scheme indicates to contiguous select high-end addresses. For instance, address range 176-200 is selected from SU 1, address range 276-300 is selected from SU 2, and address range 376-400 is selected from SU 3.

The transferring of addresses further includes associating the addresses to be transferred with the additional SU and disassociating the addresses to be transferred from the legacy SUs. The first address range migration step further includes transferring slices associated with the transfer addresses. The transferring of slices includes retrieving slices from the legacy SUs and storing slices and the additional SU. Migration of the address range mapping may end with the first step and alternatively may continue with a second step of optimization as discussed in greater detail with reference to FIG. 9C.

FIG. 9C is a diagram illustrating another example 903 of an address range mapping in accordance with the present invention. This includes a diagram illustrating another example of an address range mapping for a set of legacy distributed storage and task (DST) execution units 1-3 of a common site where additional SU 4 is added in a second address range migration step to the common site providing additional storage capacity within a site address range. In the second address range migration step, an insertion point for the additional SU is identified to facilitate more contiguous address range assignments per SU. For example, the additional SU 4 is inserted between SUs 2 and 3 and address swaps are identified between SUs 3 and 4 such that SU 3 is assigned a contiguous block of addresses at an operand of the site address range. For instance, address range 301-325 of SU 3 is identified to be transferred to SU 4 and address range 376-400 of SU 4 is identified to be transferred to SU 3. As such, inserted SU 4 is assigned to a contiguous address range (e.g., 276-325) between SUs 2 and 3 and a contiguous address range (e.g., 176-200) between SUs 1 and 2. Alternatively, a still further SU may be subsequently inserted between SUs 1 and 2 and assigned address range 176-200 when capacity utilization becomes unfavorable.

In an example of operation and implementation, a computing device includes an interface configured to interface and communicate with a dispersed or distributed storage network (DSN), a memory that stores operational instructions, and a processing module, processor, and/or processing circuitry operably coupled to the interface and memory. The processing module, processor, and/or processing circuitry is configured to execute the operational instructions to perform various operations, functions, etc. In some examples, the processing module, processor, and/or processing circuitry, when operable within the computing device based on the operational instructions, is configured to perform various operations, functions, etc. In certain examples, the processing module, processor, and/or processing circuitry, when operable within the computing device is configured to perform one or more functions that may include generation of one or more signals, processing of one or more signals, receiving of one or more signals, transmission of one or more signals, interpreting of one or more signals, etc. and/or any other operations as described herein and/or their equivalents.

In an example of operation and implementation, a storage unit (SU) includes an interface configured to interface and communicate with a dispersed or distributed storage network (DSN), a memory that stores operational instructions, and a processing module, processor, and/or processing circuitry operably coupled to the interface and memory. The processing module, processor, and/or processing circuitry is configured to execute the operational instructions to perform various operations, functions, etc. In some examples, the processing module, processor, and/or processing circuitry, when operable within the SU based on the operational instructions, is configured to perform various operations, functions, etc. in certain examples, the processing module, processor, and/or processing circuitry, when operable within the SU is configured to perform one or more functions that may include generation of one or more signals, processing of one or more signals, receiving of one or more signals, transmission of one or more signals, interpreting of one or more signals, etc. and/or any other operations as described herein and/or their equivalents.

In an example of operation and implementation, a computing device (e.g., computing device 16 of FIG. 1, FIG. 9, and/or any other diagram, example, embodiment, equivalent, etc. as described herein) is configured to obtain DSN address range assignments for the at least two other SUs based on addition of or a determination to add a first storage unit (SU) to a site that includes at least two other SUs. The computing device is also configured to determine a common address range magnitude to transfer from each of the at least two other SUs as a first SU address range divided by a total number of SUs that includes the first SU and the at least two other SUs. Then, for each of the at least two other SUs, the computing device is also configured to select a corresponding SU address range that is based on the common address range magnitude. Note that each corresponding SU address range of corresponding SU address ranges is based on a respective one of the at least two other SUs. Also, the computing device is also configured to facilitate transferring corresponding encoded data slices (EDSs) that are associated with at least one data object and corresponding DSN address range assignments for each of the corresponding SU address ranges from the at least two other SUs to the first SU.

In some examples, the computing device is also configured to identify an optimization insertion point for the first SU based on addition of the first SU to the site that includes the at least two other SUs. Also, the computing device is configured to facilitate the optimization insertion point including at least one of taking an upper address range portion of a lower adjacent SU of the at least two other SUs to the first SU or taking down a lower address range portion of an upper adjacent SU of the at least two other SUs to the first SU.

In other examples, the determination to add the first SU to the site that includes the at least two other SUs is based on at least one of receiving a request from another computing device, detecting a new SU activation within the site, or detecting an unfavorable storage capacity utilization level of at least one SU of the at least two other SUs.

In yet other examples, the corresponding SU address range that is based on the common address range magnitude corresponding to at least one of all lower end address range portions of the at least two other SUs, all upper end address range portions of the at least two other SUs, or an upper portion of a first adjacent portion and a lower portion of a second adjacent portion of an adjacent SU pair based on the addition of or the determination to add the first SU to the site that includes the at least two other SUs.

In some examples, note that a data object of the at least one data object is segmented into a plurality of data segments. A data segment of the plurality of data segments is dispersed error encoded in accordance with dispersed error encoding parameters to produce a set of encoded data slices (EDSs) of the corresponding encoded data slices (EDSs) that are associated with the at least one data object. A decode threshold number of EDSs are needed to recover the data segment. A read threshold number of EDSs provides for reconstruction of the data segment. A write threshold number of EDSs provides for a successful transfer of the set of EDSs from a first at least one location in the DSN to a second at least one location in the DSN. Also, the set of EDSs is of pillar width and includes a pillar number of EDSs. In some examples, each of the decode threshold number, the read threshold number, and the write threshold number is less than the pillar number. Also, in some examples, the write threshold number is greater than or equal to the read threshold number that is greater than or equal to the decode threshold number.

Also, in some examples, the computing device is located at a first premises that is remotely located from a second premises of at least one SU of a plurality of SUs within the DSN. In addition, in some other examples, the computing device includes a SU of a plurality of SUs within the DSN, a wireless smart phone, a laptop, a tablet, a personal computers (PC), a work station, and/or a video game device. Moreover, in some examples, the DSN includes at least one of a wireless communication system, a wire lined communication system, a non-public intranet system, a public internet system, a local area network (LAN), and/or a wide area network (WAN).

In some examples, with respect to a data object, the data object is segmented into a plurality of data segments, and a data segment of the plurality of data segments is dispersed error encoded in accordance with dispersed error encoding parameters to produce a set of encoded data slices (EDSs) (e.g., in some instances, the set of EDSs are distributedly stored in a plurality of storage units (SUs) within the DSN). In some examples, the set of EDSs is of pillar width. Also, with respect to certain implementations, note that the decode threshold number of EDSs are needed to recover the data segment, and a read threshold number of EDSs provides for reconstruction of the data segment. Also, a write threshold number of EDSs provides for a successful transfer of the set of EDSs from a first at least one location in the DSN to a second at least one location in the DSN. The set of EDSs is of pillar width and includes a pillar number of EDSs. Also, in some examples, each of the decode threshold, the read threshold, and the write threshold is less than the pillar number. Also, in some particular examples, the write threshold number is greater than or equal to the read threshold number that is greater than or equal to the decode threshold number.

Note that the computing device as described herein may be located at a first premises that is remotely located from a second premises associated with at least one other SU, dispersed storage (DS) unit, computing device, at least one SU of a plurality of SUs within the DSN (e.g., such as a plurality of SUs that are implemented to store distributedly a set of EDSs), etc. In addition, note that such a computing device as described herein may be implemented as any of a number of different devices including a managing unit that is remotely located from another SU, DS unit, computing device, etc. within the DSN and/or other device within the DSN, an integrity processing unit that is remotely located from another computing device and/or other device within the DSN, a scheduling unit that is remotely located from another computing device and/or SU within the DSN, and/or other device. Also, note that such a computing device as described herein may be of any of a variety of types of devices as described herein and/or their equivalents including a DS unit and/or SU included within any group and/or set of DS units and/or SUs within the DSN, a wireless smart phone, a laptop, a tablet, a personal computers (PC), a work station, and/or a video game device, and/or any type of computing device or communication device. Also, note also that the DSN may be implemented to include and/or be based on any of a number of different types of communication systems including a wireless communication system, a wire lined communication system, a non-public intranet system, a public internet system, a local area network (LAN), and/or a wide area network (WAN). Also, in some examples, any device configured to support communications within such a DSN may be also be configured to and/or specifically implemented to support communications within a satellite communication system, a wireless communication system, a wired communication system, a fiber-optic communication system, and/or a mobile communication system (and/or any other type of communication system implemented using any type of communication medium or media).

Note that the storage unit (SU) as described herein may be located at a first premises that is remotely located from a second premises associated with at least one other SU, dispersed storage (DS) unit, computing device, at least one SU of a plurality of SUs within the DSN (e.g., such as a plurality of SUs that are implemented to store distributedly a set of EDSs), etc. In addition, note that such a SU as described herein may be implemented as any of a number of different devices including a managing unit that is remotely located from another SU, DS unit, computing device, etc. within the DSN and/or other device within the DSN, an integrity processing unit that is remotely located from another computing device and/or other device within the DSN, a scheduling unit that is remotely located from another computing device and/or SU within the DSN, and/or other device. Also, note that such a SU as described herein may be of any of a variety of types of devices as described herein and/or their equivalents including a DS unit and/or SU included within any group and/or set of DS units and/or SUs within the DSN, a wireless smart phone, a laptop, a tablet, a personal computers (PC), a work station, and/or a video game device, and/or any type of computing device or communication device. Also, note also that the DSN may be implemented to include and/or be based on any of a number of different types of communication systems including a wireless communication system, a wire lined communication system, a non-public intranet system, a public internet system, a local area network (LAN), and/or a wide area network (WAN). Also, in some examples, any device configured to support communications within such a DSN may be also be configured to and/or specifically implemented to support communications within a satellite communication system, a wireless communication system, a wired communication system, a fiber-optic communication system, and/or a mobile communication system (and/or any other type of communication system implemented using any type of communication medium or media).

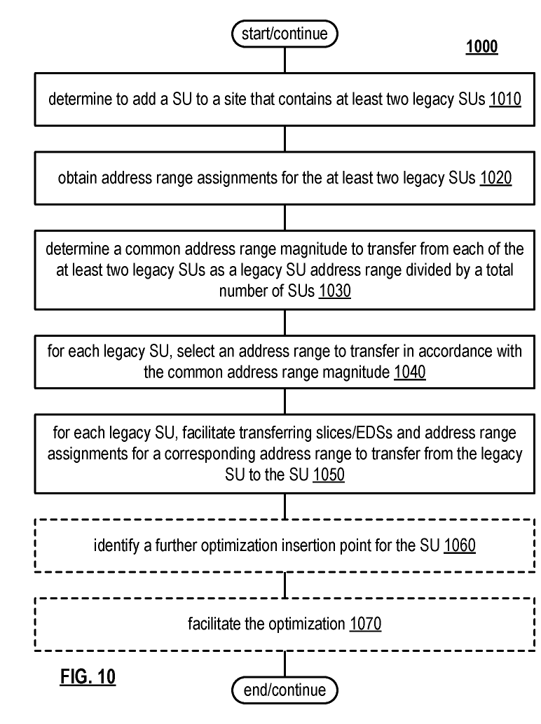

FIG. 10 is a flowchart illustrating an example of updating an address range assignment in accordance with the present invention. This diagram includes a flowchart illustrating an example of updating an address range assignment. The method 1000 begins at a step 1010 where a processing module (e.g., such as of a distributed storage (DS) client module, and alternatively, or in combination with, a computing device, processing circuitry, and/or any other component(s) including those described herein such as may be implemented within a dispersed or distributed storage network (DSN)) determines to add a storage unit (SU) to a site that contains at least two legacy SUs. The determining may be based on one or more of receiving a request, detecting a new SU activation, and/or detecting an unfavorable storage capacity utilization level. The method 1000 continues at the step 1020 where the processing module obtains address range assignments for the at least two legacy SUs. The obtaining includes at least one of initiating a query, a lookup, and/or receiving the address range assignments.

The method 1000 continues at the step 1030 of the processing module determines a common address range magnitude to transfer from each of the least two legacy SUs as a legacy SU address range divided by a total number of units. In some examples, the transfer amount from each legacy SU is substantially and/or approximately the same (e.g., within 0.5%, 1%, 5%, 10%, or any other desired number by which substantially and/or approximately the same is determined or defined). For example, considering an example of 4 legacy SUs with a total amount of 100 slices/EDS stored therein, then the amount transferred from each legacy SU is 100/4=25, so each legacy SU contributes 25 to each of the newly added SU(s).

For each legacy SU, the method 1000 continues at the step 1040 where the processing module selects an address range to transfer in accordance with the common address range magnitude to transfer (e.g., in accordance with selection scheme). For example, this may be performed in some examples with respect to all lower ends, all middle portions, all upper ends, an upper of a first adjacent and a lower of a second adjacent of adjacent pair of SUs when inserting.

For each legacy SU, the method 1000 continues at the step 1050 where the processing module facilitates transferring slices and address range assignments for corresponding address range to transfer from the legacy SU to the SU (e.g., move slices, update address tables in each SU and at a system level).

In some examples, when a previous step did not insert a SU, a variant of the method 1000 operates to identify an adjacent pair of SUs and to select at least one further address range transfer. the method 1000 continues at the step 1060 where the processing module identifies a further optimization insertion point for the SU. For example, the processing module identifies the insertion point between two legacy SUs associated with an upper end of a common site address range. The method 1000 continues at the step 1070 where the processing module facilitates the optimization. For example, the processing module facilitates an address range swap and a slice swap between the SU and at least one adjacent SU associated with the insertion point. For example, with respect to such insertion, this may be performed by taking an upper address range portion of a lower adjacent SU and/or taking down a lower address range portion of an upper adjacent SU.

Based on addition of or a determination to add a first storage unit (SU) to a site that includes at least two other SUs, variants of the method 1000 operate by obtaining (e.g., via an interface of the computing device that is configured to interface and communicate with a dispersed or distributed storage network (DSN)) DSN address range assignments for the at least two other SUs.

Such variants of the method 1000 also operate by determining a common address range magnitude to transfer from each of the at least two other SUs as a first SU address range divided by a total number of SUs that includes the first SU and the at least two other SUs.

For each of the at least two other SUs, such variants of the method 1000 operate by selecting a corresponding SU address range that is based on the common address range magnitude. Note that each corresponding SU address range of corresponding SU address ranges is based on a respective one of the at least two other SUs. Such variants of the method 1000 operate by facilitating (e.g., via the interface) transferring corresponding encoded data slices (EDSs) that are associated with at least one data object and corresponding DSN address range assignments for each of the corresponding SU address ranges from the at least two other SUs to the first SU.

In some examples, variants of the method 1000 also operate by identifying an optimization insertion point for the first SU based on addition of the first SU to the site that includes the at least two other SUs. This also involves facilitating the optimization insertion point including at least one of taking an upper address range portion of a lower adjacent SU of the at least two other SUs to the first SU or taking down a lower address range portion of an upper adjacent SU of the at least two other SUs to the first SU.

In other examples, within certain variants of the method 1000, the determination to add the first SU to the site that includes the at least two other SUs is based on at least one of receiving a request from another computing device, detecting a new SU activation within the site, or detecting an unfavorable storage capacity utilization level of at least one SU of the at least two other SUs.

In yet other examples, within such variants of the method 1000, the corresponding SU address range that is based on the common address range magnitude corresponding to at least one of all lower end address range portions of the at least two other SUs, all upper end address range portions of the at least two other SUs, and/or an upper portion of a first adjacent portion and a lower portion of a second adjacent portion of an adjacent SU pair based on the addition of or the determination to add the first SU to the site that includes the at least two other SUs.

Note that the computing device may be located at a first premises that is remotely located from at least one SU of a plurality of SUs within the DSN. Also, note that the computing device may be of any of a variety of types of devices as described herein and/or their equivalents including a SU of any group and/or set of SUs within the DSN, a wireless smart phone, a laptop, a tablet, a personal computers (PC), a work station, and/or a video game device. Note also that the DSN may be implemented to include or be based on any of a number of different types of communication systems including a wireless communication system, a wire lined communication systems, a non-public intranet system, a public internet system, a local area network (LAN), and/or a wide area network (WAN).

This disclosure presents, among other things, solutions that improve the operation of one or more computing devices, one or more storage units (SUs), and/or other device(s), and/or the dispersed or distributed storage network (DSN). Various aspects, embodiments, and/or examples of the invention are presented herein that effectuate improvement of the efficiency of the one or more computing devices, one or more SUs, and/or other device(s), and/or the DSN, produce concrete and tangible results, improve upon what was previously done with computers, and solve one or more computer specific problems. For example, when data is migrated between storage units (SUs), rather than forcing migrations to occur between adjacent systems (e.g., which may lead to cascades of migrations), the data may instead be migrated from any location to any other. For example, if a new SU is to be added to a site which had 10 SUs, rather than migrating between the two neighbor SUs, all 10 of the existing SUs may send 1/11th of their data to the new SU. The new SU now possesses 10 different namespace ranges, instead of 1. As such, there is a trade-off between minimizing migration and simplifying the namespace to store mapping. Various implementations may optimize the trade-off different. For example, a first implementation optimizes the migration relatively more than simplification of the namespace to store the mapping. A second implementation optimizes the migration relatively less than simplification of the namespace to store the mapping. Any desired blend of optimization of such considerations may be performed in accordance with various aspects, embodiments, and/or examples of the invention (and/or their equivalents).

It is noted that terminologies as may be used herein such as bit stream, stream, signal sequence, etc. (or their equivalents) have been used interchangeably to describe digital information whose content corresponds to any of a number of desired types (e.g., data, video, speech, text, graphics, audio, etc. any of which may generally be referred to as ‘data’).

As may be used herein, the terms “substantially” and “approximately” provides an industry-accepted tolerance for its corresponding term and/or relativity between items. For some industries, an industry-accepted tolerance is less than one percent and, for other industries, the industry-accepted tolerance is 10 percent or more. Other examples of industry-accepted tolerance range from less than one percent to fifty percent. Industry-accepted tolerances correspond to, but are not limited to, component values, integrated circuit process variations, temperature variations, rise and fall times, thermal noise, dimensions, signaling errors, dropped packets, temperatures, pressures, material compositions, and/or performance metrics. Within an industry, tolerance variances of accepted tolerances may be more or less than a percentage level (e.g., dimension tolerance of less than +/−1%). Some relativity between items may range from a difference of less than a percentage level to a few percent. Other relativity between items may range from a difference of a few percent to magnitude of differences.

As may also be used herein, the term(s) “configured to”, “operably coupled to”, “coupled to”, and/or “coupling” includes direct coupling between items and/or indirect coupling between items via an intervening item (e.g., an item includes, but is not limited to, a component, an element, a circuit, and/or a module) where, for an example of indirect coupling, the intervening item does not modify the information of a signal but may adjust its current level, voltage level, and/or power level. As may further be used herein, inferred coupling (i.e., where one element is coupled to another element by inference) includes direct and indirect coupling between two items in the same manner as “coupled to”.

As may even further be used herein, the term “configured to”, “operable to”, “coupled to”, or “operably coupled to” indicates that an item includes one or more of power connections, input(s), output(s), etc., to perform, when activated, one or more its corresponding functions and may further include inferred coupling to one or more other items. As may still further be used herein, the term “associated with”, includes direct and/or indirect coupling of separate items and/or one item being embedded within another item.

As may be used herein, the term “compares favorably”, indicates that a comparison between two or more items, signals, etc., provides a desired relationship. For example, when the desired relationship is that signal 1 has a greater magnitude than signal 2, a favorable comparison may be achieved when the magnitude of signal 1 is greater than that of signal 2 or when the magnitude of signal 2 is less than that of signal 1. As may be used herein, the term “compares unfavorably”, indicates that a comparison between two or more items, signals, etc., fails to provide the desired relationship.

As may be used herein, one or more claims may include, in a specific form of this generic form, the phrase “at least one of a, b, and c” or of this generic form “at least one of a, b, or c”, with more or less elements than “a”, “b”, and “c”. In either phrasing, the phrases are to be interpreted identically. In particular, “at least one of a, b, and c” is equivalent to “at least one of a, b, or c” and shall mean a, b, and/or c. As an example, it means: “a” only, “b” only, “c” only, “a” and “b”, “a” and “c”, “b” and “c”, and/or “a”, “b”, and “c”.

As may also be used herein, the terms “processing module”, “processing circuit”, “processor”, “processing circuitry”, and/or “processing unit” may be a single processing device or a plurality of processing devices. Such a processing device may be a microprocessor, micro-controller, digital signal processor, microcomputer, central processing unit, field programmable gate array, programmable logic device, state machine, logic circuitry, analog circuitry, digital circuitry, and/or any device that manipulates signals (analog and/or digital) based on hard coding of the circuitry and/or operational instructions. The processing module, module, processing circuit, processing circuitry, and/or processing unit may be, or further include, memory and/or an integrated memory element, which may be a single memory device, a plurality of memory devices, and/or embedded circuitry of another processing module, module, processing circuit, processing circuitry, and/or processing unit. Such a memory device may be a read-only memory, random access memory, volatile memory, non-volatile memory, static memory, dynamic memory, flash memory, cache memory, and/or any device that stores digital information. Note that if the processing module, module, processing circuit, processing circuitry, and/or processing unit includes more than one processing device, the processing devices may be centrally located (e.g., directly coupled together via a wired and/or wireless bus structure) or may be distributedly located (e.g., cloud computing via indirect coupling via a local area network and/or a wide area network). Further note that if the processing module, module, processing circuit, processing circuitry and/or processing unit implements one or more of its functions via a state machine, analog circuitry, digital circuitry, and/or logic circuitry, the memory and/or memory element storing the corresponding operational instructions may be embedded within, or external to, the circuitry comprising the state machine, analog circuitry, digital circuitry, and/or logic circuitry. Still further note that, the memory element may store, and the processing module, module, processing circuit, processing circuitry and/or processing unit executes, hard coded and/or operational instructions corresponding to at least some of the steps and/or functions illustrated in one or more of the Figures. Such a memory device or memory element can be included in an article of manufacture.

One or more embodiments have been described above with the aid of method steps illustrating the performance of specified functions and relationships thereof. The boundaries and sequence of these functional building blocks and method steps have been arbitrarily defined herein for convenience of description. Alternate boundaries and sequences can be defined so long as the specified functions and relationships are appropriately performed. Any such alternate boundaries or sequences are thus within the scope and spirit of the claims. Further, the boundaries of these functional building blocks have been arbitrarily defined for convenience of description. Alternate boundaries could be defined as long as the certain significant functions are appropriately performed. Similarly, flow diagram blocks may also have been arbitrarily defined herein to illustrate certain significant functionality.

To the extent used, the flow diagram block boundaries and sequence could have been defined otherwise and still perform the certain significant functionality. Such alternate definitions of both functional building blocks and flow diagram blocks and sequences are thus within the scope and spirit of the claims. One of average skill in the art will also recognize that the functional building blocks, and other illustrative blocks, modules and components herein, can be implemented as illustrated or by discrete components, application specific integrated circuits, processors executing appropriate software and the like or any combination thereof.

In addition, a flow diagram may include a “start” and/or “continue” indication. The “start” and “continue” indications reflect that the steps presented can optionally be incorporated in or otherwise used in conjunction with one or more other routines. In addition, a flow diagram may include an “end” and/or “continue” indication. The “end” and/or “continue” indications reflect that the steps presented can end as described and shown or optionally be incorporated in or otherwise used in conjunction with one or more other routines. In this context, “start” indicates the beginning of the first step presented and may be preceded by other activities not specifically shown. Further, the “continue” indication reflects that the steps presented may be performed multiple times and/or may be succeeded by other activities not specifically shown. Further, while a flow diagram indicates a particular ordering of steps, other orderings are likewise possible provided that the principles of causality are maintained.

The one or more embodiments are used herein to illustrate one or more aspects, one or more features, one or more concepts, and/or one or more examples. A physical embodiment of an apparatus, an article of manufacture, a machine, and/or of a process may include one or more of the aspects, features, concepts, examples, etc. described with reference to one or more of the embodiments discussed herein. Further, from figure to figure, the embodiments may incorporate the same or similarly named functions, steps, modules, etc. that may use the same or different reference numbers and, as such, the functions, steps, modules, etc. may be the same or similar functions, steps, modules, etc. or different ones.

Unless specifically stated to the contra, signals to, from, and/or between elements in a figure of any of the figures presented herein may be analog or digital, continuous time or discrete time, and single-ended or differential. For instance, if a signal path is shown as a single-ended path, it also represents a differential signal path. Similarly, if a signal path is shown as a differential path, it also represents a single-ended signal path. While one or more particular architectures are described herein, other architectures can likewise be implemented that use one or more data buses not expressly shown, direct connectivity between elements, and/or indirect coupling between other elements as recognized by one of average skill in the art.

The term “module” is used in the description of one or more of the embodiments. A module implements one or more functions via a device such as a processor or other processing device or other hardware that may include or operate in association with a memory that stores operational instructions. A module may operate independently and/or in conjunction with software and/or firmware. As also used herein, a module may contain one or more sub-modules, each of which may be one or more modules.

As may further be used herein, a computer readable memory includes one or more memory elements. A memory element may be a separate memory device, multiple memory devices, or a set of memory locations within a memory device. Such a memory device may be a read-only memory, random access memory, volatile memory, non-volatile memory, static memory, dynamic memory, flash memory, cache memory, and/or any device that stores digital information. The memory device may be in a form a solid-state memory, a hard drive memory, cloud memory, thumb drive, server memory, computing device memory, and/or other physical medium for storing digital information.

While particular combinations of various functions and features of the one or more embodiments have been expressly described herein, other combinations of these features and functions are likewise possible. The present disclosure is not limited by the particular examples disclosed herein and expressly incorporates these other combinations.

What is claimed is:

1. A computing device comprising:
an interface configured to interface and communicate with a dispersed or distributed storage network (DSN);
memory that stores operational instructions; and
processing circuitry operably coupled to the interface and to the memory, wherein the processing circuitry is configured to execute the operational instructions to:
based on addition of or a determination to add a first storage unit (SU) to a site that includes at least two other SUs, obtain DSN address range assignments for the at least two other SUs;
determine a common address range magnitude to transfer from each of the at least two other SUs as a first SU address range divided by a total number of SUs that includes the first SU and the at least two other SUs; and
for each of the at least two other SUs:
select a corresponding SU address range that is based on the common address range magnitude, wherein each corresponding SU address range of corresponding SU address ranges is based on a respective one of the at least two other SUs; and
facilitate transferring corresponding encoded data slices (EDSs) that are associated with at least one data object and corresponding DSN address range assignments for each of the corresponding SU address ranges from the at least two other SUs to the first SU.

2. The computing device of claim 1, wherein the processing circuitry is further configured to execute the operational instructions to:
identify an optimization insertion point for the first SU based on addition of the first SU to the site that includes the at least two other SUs; and
facilitate the optimization insertion point including at least one of taking an upper address range portion of a lower adjacent SU of the at least two other SUs to the first SU or taking down a lower address range portion of an upper adjacent SU of the at least two other SUs to the first SU.

3. The computing device of claim 1, wherein the determination to add the first SU to the site that includes the at least two other SUs is based on at least one of receiving a request from another computing device, detecting a new SU activation within the site, or detecting an unfavorable storage capacity utilization level of at least one SU of the at least two other SUs.

4. The computing device of claim 1, wherein the corresponding SU address range that is based on the common address range magnitude corresponding to at least one of all lower end address range portions of the at least two other SUs, all upper end address range portions of the at least two other SUs, or an upper portion of a first adjacent portion and a lower portion of a second adjacent portion of an adjacent SU pair based on the addition of or the determination to add the first SU to the site that includes the at least two other SUs.

5. The computing device of claim 1, wherein:
a data object of the at least one data object is segmented into a plurality of data segments, wherein a data segment of the plurality of data segments is dispersed error encoded in accordance with dispersed error encoding parameters to produce a set of encoded data slices (EDSs) of the corresponding encoded data slices (EDSs) that are associated with the at least one data object;
a decode threshold number of EDSs are needed to recover the data segment;
a read threshold number of EDSs provides for reconstruction of the data segment;
a write threshold number of EDSs provides for a successful transfer of the set of EDSs from a first at least one location in the DSN to a second at least one location in the DSN;
the set of EDSs is of pillar width and includes a pillar number of EDSs;
each of the decode threshold number, the read threshold number, and the write threshold number is less than the pillar number; and
the write threshold number is greater than or equal to the read threshold number that is greater than or equal to the decode threshold number.

6. The computing device of claim 1, wherein the computing device is located at a first premises that is remotely located from a second premises of at least one SU of a plurality of SUs within the DSN.

7. The computing device of claim 1 further comprising:
a SU of a plurality of SUs within the DSN, a wireless smart phone, a laptop, a tablet, a personal computers (PC), a work station, or a video game device.

8. The computing device of claim 1, wherein the DSN includes at least one of a wireless communication system, a wire lined communication system, a non-public intranet system, a public internet system, a local area network (LAN), or a wide area network (WAN).

9. A computing device comprising:
an interface configured to interface and communicate with a dispersed or distributed storage network (DSN);
memory that stores operational instructions; and
processing circuitry operably coupled to the interface and to the memory, wherein the processing circuitry is configured to execute the operational instructions to:
based on addition of or a determination to add a first storage unit (SU) to a site that includes at least two other SUs, obtain DSN address range assignments for the at least two other SUs, wherein the determination to add the first SU to the site that includes the at least two other SUs is based on at least one of receiving a request from another computing device, detecting a new SU activation within the site, or detecting an unfavorable storage capacity utilization level of at least one SU of the at least two other SUs;
determine a common address range magnitude to transfer from each of the at least two other SUs as a first SU address range divided by a total number of SUs that includes the first SU and the at least two other SUs; and
for each of the at least two other SUs:
select a corresponding SU address range that is based on the common address range magnitude, wherein each corresponding SU address range of corresponding SU address ranges is based on a respective one of the at least two other SUs; and
facilitate transferring corresponding encoded data slices (EDSs) that are associated with at least one data object and corresponding DSN address range assignments for each of the corresponding SU address ranges from the at least two other SUs to the first SU; and
identify an optimization insertion point for the first SU based on addition of the first SU to the site that includes the at least two other SUs; and
facilitate the optimization insertion point including at least one of taking an upper address range portion of a lower adjacent SU of the at least two other SUs to the first SU or taking down a lower address range portion of an upper adjacent SU of the at least two other SUs to the first SU.

10. The computing device of claim 9, wherein the corresponding SU address range that is based on the common address range magnitude corresponding to at least one of all lower end address range portions of the at least two other SUs, all upper end address range portions of the at least two other SUs, or an upper portion of a first adjacent portion and a lower portion of a second adjacent portion of an adjacent SU pair based on the addition of or the determination to add the first SU to the site that includes the at least two other SUs.

11. The computing device of claim 9, wherein:
a data object of the at least one data object is segmented into a plurality of data segments, wherein a data segment of the plurality of data segments is dispersed error encoded in accordance with dispersed error encoding parameters to produce a set of encoded data slices (EDSs) of the corresponding encoded data slices (EDSs) that are associated with the at least one data object;
a decode threshold number of EDSs are needed to recover the data segment;
a read threshold number of EDSs provides for reconstruction of the data segment;
a write threshold number of EDSs provides for a successful transfer of the set of EDSs from a first at least one location in the DSN to a second at least one location in the DSN;
the set of EDSs is of pillar width and includes a pillar number of EDSs;
each of the decode threshold number, the read threshold number, and the write threshold number is less than the pillar number; and
the write threshold number is greater than or equal to the read threshold number that is greater than or equal to the decode threshold number.

12. The computing device of claim 9 further comprising:
a SU of a plurality of SUs within the DSN, a wireless smart phone, a laptop, a tablet, a personal computers (PC), a work station, or a video game device.

13. The computing device of claim 9, wherein the DSN includes at least one of a wireless communication system, a wire lined communication system, a non-public intranet system, a public internet system, a local area network (LAN), or a wide area network (WAN).

14. A method for execution by a computing device, the method comprising:
based on addition of or a determination to add a first storage unit (SU) to a site that includes at least two other SUs, obtaining, via an interface of the computing device that is configured to interface and communicate with a dispersed or distributed storage network (DSN), DSN address range assignments for the at least two other SUs;
determining a common address range magnitude to transfer from each of the at least two other SUs as a first SU address range divided by a total number of SUs that includes the first SU and the at least two other SUs; and
for each of the at least two other SUs:
selecting a corresponding SU address range that is based on the common address range magnitude, wherein each corresponding SU address range of corresponding SU address ranges is based on a respective one of the at least two other SUs; and
facilitating, via the interface, transferring corresponding encoded data slices (EDSs) that are associated with at least one data object and corresponding DSN address range assignments for each of the corresponding SU address ranges from the at least two other SUs to the first SU.

15. The method of claim 14 further comprising:
identifying an optimization insertion point for the first SU based on addition of the first SU to the site that includes the at least two other SUs; and
facilitating the optimization insertion point including at least one of taking an upper address range portion of a lower adjacent SU of the at least two other SUs to the first SU or taking down a lower address range portion of an upper adjacent SU of the at least two other SUs to the first SU.

16. The method of claim 14, wherein the determination to add the first SU to the site that includes the at least two other SUs is based on at least one of receiving a request from another computing device, detecting a new SU activation within the site, or detecting an unfavorable storage capacity utilization level of at least one SU of the at least two other SUs.

17. The method of claim 14, wherein the corresponding SU address range that is based on the common address range magnitude corresponding to at least one of all lower end address range portions of the at least two other SUs, all upper end address range portions of the at least two other SUs, or an upper portion of a first adjacent portion and a lower portion of a second adjacent portion of an adjacent SU pair based on the addition of or the determination to add the first SU to the site that includes the at least two other SUs.

18. The method of claim 14, wherein:
a data object of the at least one data object is segmented into a plurality of data segments, wherein a data segment of the plurality of data segments is dispersed error encoded in accordance with dispersed error encoding parameters to produce a set of encoded data slices (EDSs) of the corresponding encoded data slices (EDSs) that are associated with the at least one data object;
a decode threshold number of EDSs are needed to recover the data segment;
a read threshold number of EDSs provides for reconstruction of the data segment;
a write threshold number of EDSs provides for a successful transfer of the set of EDSs from a first at least one location in the DSN to a second at least one location in the DSN;
the set of EDSs is of pillar width and includes a pillar number of EDSs;
each of the decode threshold number, the read threshold number, and the write threshold number is less than the pillar number; and
the write threshold number is greater than or equal to the read threshold number that is greater than or equal to the decode threshold number.

19. The method of claim 14, wherein the computing device includes a SU of a plurality of SUs within the DSN, a wireless smart phone, a laptop, a tablet, a personal computers (PC), a work station, or a video game device.

20. The method of claim 14, wherein the DSN includes at least one of a wireless communication system, a wire lined communication system, a non-public intranet system, a public internet system, a local area network (LAN), or a wide area network (WAN).
